(19) United States
(12) Patent Application Publication
(10) Pub. No.: US 2025/0391723 A1
(43) Pub. Date: Dec. 25, 2025

(54) SEMICONDUCTOR DIE AND METHOD OF MANUFACTURING THE SAME

(71) Applicant: Infineon Technologies AG, Neubiberg (DE)

(72) Inventors: Thomas SÖLLRADL, Arnoldstein (AT); Jochen HILSENBECK, Villach (AT); Thomas GANNER, Krumpendorf am Wörthersee (AT); Konrad SCHRAML, Feldkirchen (DE); Tobias WASSERMANN, Soest (DE); Dethard PETERS, Höchstadt (DE)

(21) Appl. No.: 19/181,828

(22) Filed: Apr. 17, 2025

(30) Foreign Application Priority Data
Apr. 18, 2024 (DE) 102024203633.1

(51) Int. Cl. H01L 23/31; H01L 21/04; H01L 23/29; H01L 23/528; H01L 23/532

(52) U.S. Cl. CPC H01L 23/3192; H01L 21/045; H01L 23/291; H01L 23/293; H01L 23/3171; H01L 23/5283; H01L 23/53228

(57) ABSTRACT

The disclosure relates to a semiconductor die, comprising a silicon carbide (SiC) semiconductor body; a passivation system on a first side of the SiC semiconductor body; the passivation system comprising an inorganic passivation layer system and an organic layer on the inorganic passivation layer system, a lateral edge of the inorganic passivation layer system arranged on the SiC semiconductor body, wherein the inorganic passivation layer system is laterally set back under the organic layer, the lateral edge of the inorganic passivation layer system being covered by the organic layer.

### RELATED APPLICATION

This application claims priority to German Patent Application No. 102024203633.1, filed on Apr. 18, 2024, entitled “SEMICONDUCTOR DIE AND METHOD OF MANUFACTURING THE SAME”, which is incorporated by reference herein in its entirety.

### TECHNICAL FIELD

The present disclosure relates to a semiconductor die comprising a semiconductor body.

### BACKGROUND

In embodiments of this application, the semiconductor body is made of silicon carbide (SiC) which has a comparably wide band gap, e.g. compared to silicon. This can for instance be of interest for power semiconductor devices in high voltage and/or high current applications. In the semiconductor body, a device structure with a load terminal or terminals can be formed, for example a transistor structure having a source terminal and a drain terminal. For a wiring and contacting of the device structure, a metallization can be formed on the semiconductor body.

### SUMMARY

Examples of the present application are directed at an advantageous semiconductor die.

In an embodiment, a semiconductor die comprises a silicon carbide (SiC) semiconductor body and a passivation system on a first side of the SiC semiconductor body. The passivation system comprises an inorganic passivation layer system and an organic layer, wherein a lateral edge of the inorganic passivation layer system is arranged on the SiC semiconductor body. The organic layer may cover this lateral edge of the inorganic passivation layer system, e.g. extend laterally further than the inorganic passivation layer system. In other words, the lateral edge of the inorganic passivation layer system is laterally set back under the organic layer.

As viewed in a sectional plane perpendicular to the lateral edge of the inorganic passivation layer system, the organic layer may extend on the inorganic passivation layer system on one side of the lateral edge and cover the lateral edge of the inorganic passivation layer system towards the other side, e.g. laterally outwards (towards a lateral edge of the SiC semiconductor body). The organic layer covering the lateral edge of the inorganic passivation layer system can for instance reduce or slow down a silicon carbide oxidation, e.g. an oxidation of the SiC semiconductor body aside or below the inorganic passivation layer system.

Such an oxidation might be triggered or driven by humidity, e.g. in combination with electrical fields. For instance, at the lateral edge of the inorganic passivation layer system, which lies on the SiC semiconductor body, a SiC oxidation might introduce mechanical stress and cause a delamination risk. By extending the organic layer, e.g. imide layer, above the lateral edge, a SiC oxidation at this geometrically critical location can be at least delayed.

Further embodiments and features are provided in the claims and throughout this disclosure. Therein, the individual features shall be disclosed independently of a specific claim category, the disclosure relates to apparatus and device aspects but also to method and use aspects. If for instance a die manufactured in a specific way is described, this is also a disclosure of a respective manufacturing process, and vice versa. In general words, embodiments of the present application aim at providing an organic layer with an overlap, e.g. laterally outwards, on a lateral edge of an inorganic layer, i.e. covering the lateral edge of the inorganic layer.

Generally, when reference is made to an arrangement of a layer or lateral edge of the layer “on” another layer or entity, e.g. on the SiC semiconductor body, this does not necessarily imply an arrangement directly adjacent to this layer or entity. In other words, an additional layer may be arranged in between the inorganic passivation layer system and the first side of the SiC semiconductor body, e.g. an aluminum oxide layer. For example, only the aluminum oxide layer may be arranged in between the inorganic passivation layer system and the first side of the SiC semiconductor body. The additional layer may for instance serve as an adhesion promoter and/or etch stop layer. It can for instance have a thickness of not more than 30 nm, 20 nm or 15 nm, possible lower limits being for instance 3 nm or 5 nm. Summarized in other words, an arrangement “on” can mean a certain distance, e.g. a comparably small distance of no more than 100 nm, 50 nm, 30 nm, 20 nm or 15 nm, or an arrangement “directly on”.

The lateral edge of the additional layer may be arranged on the SiC semiconductor body, e.g. where the lateral edge of the inorganic passivation layer system is arranged. Alternatively, the additional layer may extend further, e.g. laterally outwards, than the inorganic passivation layer system. Independently of these details, the coverage, e.g. by the organic layer, may prevent or slow down a humidity and/or ionic contamination. As an alternative to the additional layer below, however, the inorganic passivation layer system, i.e. the lateral edge thereof, may also be arranged directly on the SiC semiconductor body. In addition or as an alternative, the organic layer may be arranged directly on the first side of the semiconductor body aside the inorganic passivation layer system.

Generally, the SiC semiconductor body may comprise a SiC semiconductor substrate, for instance in combination with one or a plurality of epitaxial SiC layers thereon. That side of an uppermost epitaxial SiC layer, which faces away from the SiC substrate, may be the “first side” of the SiC semiconductor body. Vice versa, that side of the SiC substrate, which faces away from the epitaxial SiC layer or layers, may be the “second side” of the SiC semiconductor body.

In an embodiment, the inorganic passivation layer system is laterally set back under the organic layer by at least 1 μm, further lower limits being for instance at least 2 μm or 2.5 μm. Possible upper limits can for instance be at most 50 μm, 30 μm or 20 μm. In detail, a respective distance may be taken in a sectional plane perpendicular to the lateral edge of the inorganic passivation layer system, i.e. the distance between the lateral edge of the inorganic passivation layer system and a lateral edge of the organic layer (at the lower end of the organic layer).

In an embodiment, the lateral edge of the inorganic passivation layer system is an outer lateral edge which faces towards the lateral edge of the SiC semiconductor body (whereas an inner lateral edge may be oriented towards the active area). Near the lateral edge of the SiC semiconductor body, an electrical field may be present, originating for instance from a backside potential which can reach from the backside (second side) to the frontside (first side) at the lateral edge of the SiC semiconductor body and which might trigger or drive oxidation processes. The outer lateral edge may for instance be the outermost lateral edge of the inorganic passivation layer or system, e.g. no other element of the inorganic passivation layer system being arranged further outward.

Generally, “outward(s)” and “outermost” relate to the lateral position with respect to the respective lateral edge of the SiC semiconductor body, i.e. mean closer or closest to this lateral edge. The elements discussed with respect to their relative position are for instance arranged on the same side of an active area of the die, i.e. at the same lateral edge of the SiC semiconductor body. Therein, similar structures may be arranged at the other lateral edges of the SiC semiconductor body, which, however, is not mandatory.

The outer lateral edge of the inorganic passivation layer system may be offset inwards from the lateral edge of the SiC semiconductor body, e.g. lie parallel to the lateral edge of the SiC semiconductor body as seen in a vertical top view. Laterally outside of the outer lateral edge of the inorganic passivation layer system, the SiC semiconductor body in embodiments without an additional layer may be exposed, e.g. be not covered by an inorganic layer, wherein the organic layer may provide a coverage at least over a lateral portion.

The lateral edge, e.g. outer lateral edge, of the inorganic passivation layer system may be arranged between the lateral edge of the SiC semiconductor body and an active area. In other words, the lateral edge of the inorganic passivation layer system may be arranged in an edge termination region. In the active area, a device structure may be formed in the SiC semiconductor body, comprising for instance a first load terminal arranged at the first side of the SiC semiconductor body. Additionally, the device structure may comprise a second load terminal, e.g. at a vertically opposite second side of the SiC semiconductor body. The device structure can for instance be a FET having a source terminal/region and a drain terminal/region in the SiC semiconductor body, e.g. the source region at the first side of the SiC semiconductor body and the drain region at the second side thereof. In other words, the load pad in the metallization may be a source pad connected to a source terminal of the device structure.

In addition to the source region and the drain region, the device may comprise a body region to which a gate electrode capacitively couples. Additionally, a drift region may be arranged between the body region and the drain region, e.g. made of the same doping type but with a lower concentration than the drain region. The source region and drain region and, if present, drift region may be made of a first doping type, the body region made of a second doping type. In the illustrated embodiments, the first doping type is n-type and the second doping type is p-type.

In an embodiment, the semiconductor die comprises an insulating layer on the first side of the SiC semiconductor body. The insulating layer can for instance be arranged directly on the first side, namely adjacent to the SiC semiconductor body. It may serve as an interlayer dielectric, e.g. define a contact structure between a metallization above and the semiconductor body below. The insulating layer may comprise an oxide layer, for example a borophosphosilicate glass (BPSG) layer. In other words, the insulating layer may comprise a doped oxide layer, for example in addition to an undoped oxide layer. The insulating layer may for instance have a total thickness of at least 0.5 μm and/or at most 3 μm.

The insulating layer may have an outer the lateral edge on the SiC semiconductor body, the outer lateral edge of the insulating layer being offset inwards from the lateral edge of the SiC semiconductor body. The outer lateral edge of the insulating layer may be covered by the inorganic passivation layer system, so that in other words the outer lateral edge of the inorganic passivation layer system is arranged on a lateral position between the lateral edge of the SiC semiconductor body and the outer lateral edge of the insulating layer.

In an embodiment, the outer lateral edge of the insulating layer is offset inwards from the lateral edge of the inorganic passivation layer system by at least 1 μm, further lower limits being for instance at least 2 μm, 3 μm or 4 μm. Possible upper limits can for example be at most 20 μm or 10 μm. In detail, a respective distance may be taken in a sectional plane perpendicular to the lateral edge of the inorganic passivation layer system, i.e. the minimum distance between the lateral edge of the inorganic passivation layer system and the outer lateral edge of the insulating layer.

In an embodiment, an outer lateral edge of the insulating layer is offset inwards from an outer lateral edge of the organic layer, e.g. imide layer. This may apply in case of a passivation system with or without an inorganic passivation layer system. In the latter case, the organic layer may be arranged on the insulating layer, wherein the arrangement “on” can mean a certain distance, e.g. a comparably small distance of no more than 100 nm, 50 nm, 30 nm, 20 nm or 15 nm, or an arrangement “directly on”.

Summarized in other words, it shall be disclosed:

A semiconductor die, comprising:
a semiconductor body, e.g. silicon carbide semiconductor body;
an insulating layer on a first side of the semiconductor body;
an organic layer, e.g. imide layer, on the insulating layer;
   the insulating layer having an outer lateral edge on the semiconductor body and the organic layer having an outer lateral edge on the semiconductor body,
   wherein the outer lateral edge of the insulating layer is offset inwards from the outer lateral edge of the organic layer.

In an embodiment, the semiconductor die comprises a metallization on the first side of the SiC semiconductor body, an insulating layer as discussed above being for instance arranged between the SiC semiconductor body and the metallization. In case of a FET formed in the semiconductor body, the load pad can for instance be a source pad, see in detail above.

The passivation system may cover a lateral edge of the load pad, e.g. extend aside and reach onto the load pad. Therein, the passivation system may have an opening on the load pad, e.g. for a later contacting in a package or other mounting structure.

As viewed in a sectional plane perpendicular to the lateral edge of the load pad, the inorganic passivation layer system has an inner lateral end on the load pad. In general, the organic layer may be flush with the inner lateral end of the inorganic passivation layer system on the load pad. In an embodiment, however, the organic layer extends further inwards than the inorganic passivation layer system, i.e. covers the inner lateral end of the inorganic passivation layer system laterally inwards.

In an embodiment, the inorganic passivation layer system, as viewed in a sectional plane perpendicular to the lateral edge of the load pad, extends uninterrupted, i.e. without an interruption, between the lateral edge of the load pad and the inner lateral end of the inorganic passivation layer system. Alternatively, the inorganic passivation layer system may be provided with an interruption on the load pad, e.g. on a lateral position between the lateral edge of the load pad and the inner lateral end of the inorganic passivation layer system. Independently of whether or not the inorganic passivation layer system is provided with an interruption, the organic layer may extend uninterrupted, i.e. without an interruption between the opening on the load pad and the lateral edge of the load pad (and further outwards towards the lateral edge of the SiC semiconductor body).

In an embodiment, the metallization in the area of the load pad is formed with a step. Laterally outside of the step, e.g. closer to a lateral edge of the SiC semiconductor body or die, the load pad has a first thickness t₁. Laterally inside of the step, e.g. at a larger distance from the lateral edge of the SiC semiconductor body or die, the load pad has a second thickness t₂. Therein, t₁ is smaller than t₂. In other words, the load pad has a smaller thickness t₁ in an edge portion of the load pad and a larger thickness in a central portion of the load pad. The latter may, for example, have advantages in terms of thermal management or mounting and bonding, wherein the smaller thickness in the edge portion can for instance reduce a topology of the passivation system extending onto the load pad.

In an embodiment, an inner lateral position x₂, to which the passivation system extends, is arranged laterally outside of the step. In other words, the passivation system as viewed in the sectional plane extends laterally onto the load pad but ends in the edge region thereof, where the load pad has the thickness t₁. As viewed in a sectional plane, the passivation system covers the lateral edge of the load pad but not the step.

In an embodiment, an inorganic layer or inorganic layer stack covers a flank of the step in the load pad. The inorganic layer may be, or the inorganic layer stack may comprise, a silicon nitride layer and/or a silicon oxide layer. Independently of a specific material, covering the flank can for instance be advantageous in terms of migration or diffusion processes. Such processes can, by way of example, be driven by an electrical field originating from a backside potential reaching up to the first side at the lateral edge of the semiconductor body (even when the electrical field is reduced in an edge termination area or structure, a residual field strength may remain).

The flank covered by an inorganic layer or layer stack shall also be disclosed independently of the overlapping organic layer. In other words, it shall be disclosed a semiconductor die, comprising: a semiconductor body; a metallization on a first side of the semiconductor body, in which a load pad is formed; wherein the metallization in the area of the load pad is formed with a step, the load pad having a first thickness t₁ laterally outside of the step and a second thickness t₂ laterally inside of the step, where t₁ is smaller than t₂, wherein an inorganic layer or layer stack covers a flank of the step. As to possible embodiments and additional features, reference is made to the disclosure as a whole.

In an embodiment, the metallization comprises a copper layer. The copper layer may be part of a copper layer system which can for instance comprise a sputter-deposited copper layer and one or a plurality of bath-deposited copper layers on top. In an embodiment, the metallization comprises a first bath-deposited copper layer and a second bath-deposited copper layer deposited onto the first bath-deposited copper layer, wherein the second bath-deposited copper layer may be structured with respect to the first bath-deposited copper layer. In other words, the second bath-deposited copper layer may form the step in the load pad.

For a structuring of the second bath-deposited copper layer, a mask may be provided on the first bath-deposited copper layer prior to the deposition of the second bath-deposited copper layer. The step in the load pad can be formed at a lateral edge of the second bath-deposited copper layer, which is displaced inwards with respect to a lateral edge of the first bath-deposited copper layer. Alternatively, however, a copper layer or layers may be sputter-deposited, independently of whether or not a bath-deposited copper layer system is applied subsequently. In other words, a sputter-deposited copper layer or layers may be combined with a bath-deposited copper layer(s) or the copper metallization as a whole may be sputter-deposited. Also in case of the sputter-deposited copper metallization, an upper copper layer may be structured with respect to a copper layer below to form a step.

In sum, independently of whether sputter- and/or bath-deposited, all copper layers of the metallization can for instance have a thickness of at least 3 μm, further lower limits being for instance 5 μm or 7 μm. By way of example, upper limits may be 25 μm or 20 μm. Below the lowermost copper layer, e.g. sputter-deposited copper layer, a barrier layer system of the metallization may be arranged (e.g. comprising a Ti/TiN layer).

In an embodiment, the inorganic passivation layer system comprises a silicon nitride layer and a silicon oxide layer. The silicon nitride layer may be arranged below or on the silicon oxide layer. In an embodiment, the silicon oxide layer is arranged on a first silicon nitride layer, wherein a second silicon nitride layer is arranged on the silicon oxide layer, the silicon oxide layer for instance directly on the first silicon nitride layer and/or the second silicon nitride layer directly on the silicon oxide layer. The first silicon nitride layer may for instance be thinner than the silicon oxide layer and/or second silicon nitride layer. Independently of these geometrical details, the silicon oxide layer may for instance be an undoped silicon oxide layer, e.g. undoped silicon glass (USG).

In an embodiment, the semiconductor die comprises a SiC semiconductor body, an insulating layer on a first side of the SiC semiconductor body and a passivation system with an organic player, e. g. imide layer, on the insulating layer. The insulating layer may have an outer lateral edge on the SiC semiconductor body, e. g. directly on the SiC semiconductor body or with an additional layer in between (for example aluminum oxide layer, see the description above as to the arrangement “on”). Independently of these details, the outer lateral edge of the insulating layer may be covered by the organic layer, i.e. the outer lateral edge of the insulating layer being laterally set back below the organic layer.

As discussed above for the lateral edge of the inorganic passivation layer system covered by the organic layer, the coverage of the outer lateral edge of the insulating layer can for instance reduce a delamination risk (by slowing down or preventing a SiC oxidation at the edge of or even below the insulating layer). As to further details of the insulating layer, reference is made to the description above; it may for instance comprise an oxide layer (e.g. BPSG layer) and have a total thickness of at least 0.5 μm and/or at most 3 μm.

In an embodiment, an outer lateral edge of the inorganic passivation layer system is arranged on the insulating layer, i. e. an outer portion of the insulating layer being not covered by the inorganic passivation layer system. Then, the organic layer, e. g. imide layer, may cover both, the outer lateral edge of the inorganic passivation layer system on the insulating layer and the outer lateral edge of the insulating layer on the SiC semiconductor body.

In an embodiment, the organic layer has a thickness of at least 1 μm, further lower limits being for instance at least 2 μm, 3 μm, 4 μm or 5 μm. Possible upper limits may for instance be not more than 50 μm, 40 μm, 30 μm or 25 μm.

In an embodiment, the organic layer is an imide layer. The imide can for instance be a photosensitive polyimide precursor.

In an embodiment, a method of manufacturing a semiconductor die comprises:
I) forming an inorganic passivation layer system on a first side of a SiC semiconductor body, so that a lateral edge of the inorganic passivation layer system is arranged on the SiC semiconductor body (e.g. directly on or with an additional layer between);
II) forming an organic layer on the inorganic passivation layer system, which covers the lateral edge of the inorganic passivation layer system.

As to additional embodiments and features, reference is made to the disclosure as a whole.

In an embodiment, step I) comprises:
i) depositing the inorganic passivation layer system on the first side of the SiC semiconductor body;
ii) etching away the inorganic passivation layer system locally to define the lateral edge of the inorganic passivation layer system.

For step ii), a mask may be deposited on the inorganic passivation layer system. The inorganic passivation layer system may be etched away locally where the mask has an opening, for example at the lateral edge of the SiC semiconductor body and/or on a load pad formed in a metallization. Independently of these details, the mask may be removed after the inorganic passivation layer system has been etched away locally, e.g. prior to forming the organic layer in step II).

Any of these methods or method steps discussed above may be applied for manufacturing a semiconductor die discussed above.

### BRIEF DESCRIPTION OF THE DRAWINGS

Below, the semiconductor die and method of manufacturing are explained in further detail by means of exemplary embodiments. Therein, the individual features can also be relevant in a different combination.

FIG. 1 shows a cross-sectional view of a semiconductor die comprising a SiC semiconductor body and a passivation system;

FIG. 2 shows a more detailed view of a passivation system on a SiC semiconductor body;

FIG. 3 shows a schematic cross-section of a device formed in an active area of a semiconductor die;

FIGS. 4a-e illustrate different steps of manufacturing a semiconductor die with a passivation system comprising an inorganic passivation layer system and an organic layer;

FIG. 5 shows a detailed view of an embodiment of a passivation system on a SiC semiconductor body;

FIG. 6 summarizes some manufacturing steps in a flow diagram;

FIG. 7 shows a cross-sectional view of a semiconductor die comprising a SiC semiconductor body, an insulating layer and a passivation system;

FIG. 8 shows a cross-sectional view of a semiconductor die, which comprises an insulating layer and an organic layer.

### DETAILED DESCRIPTION

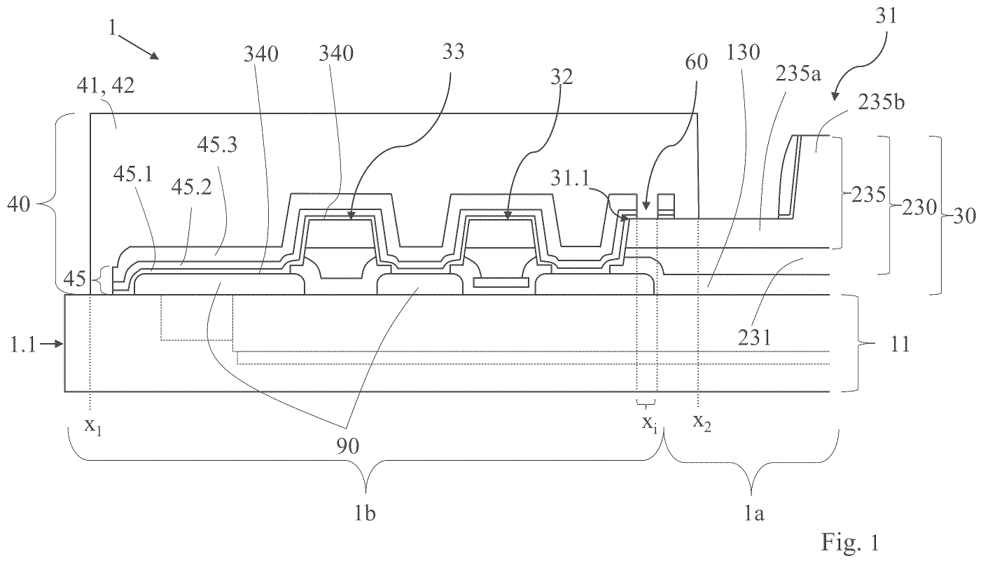

FIG. 1 shows a portion of a semiconductor die 1 in a vertical cross-section. The semiconductor die 1 comprises a silicon carbide (SiC) semiconductor body 11. On a first side 11.1 of the SiC semiconductor body 11, an insulating layer 90 is arranged. Further, a metallization 30 is formed on the SiC semiconductor body 11, which comprises a barrier layer system 130. On the barrier layer system 130, a copper layer system 230 is arranged, which in the example shown comprises a sputter-deposited copper layer 231 and a bath-deposited copper layer system 235 with a first bath-deposited copper layer 235a and a second bath-deposited copper layer 235b.

In detail, the cross-sectional view of FIG. 1 lies at a lateral edge 1.1 of the die 1, wherein an inactive area 1b is arranged laterally between the lateral edge 1.1 of the die 1 and an active area 1a shown on the right in FIG. 1. In the active area 1a, transistor device cells may be arranged (see in detail below). In the active area 1a, a load pad 31 may be formed in the metallization 30, for example a source pad connected to a source terminal of the device or device cells. In the inactive area 1b, a gate runner 32 and/or a source runner 33, each extending along the active area 1a, may be formed in the metallization 30.

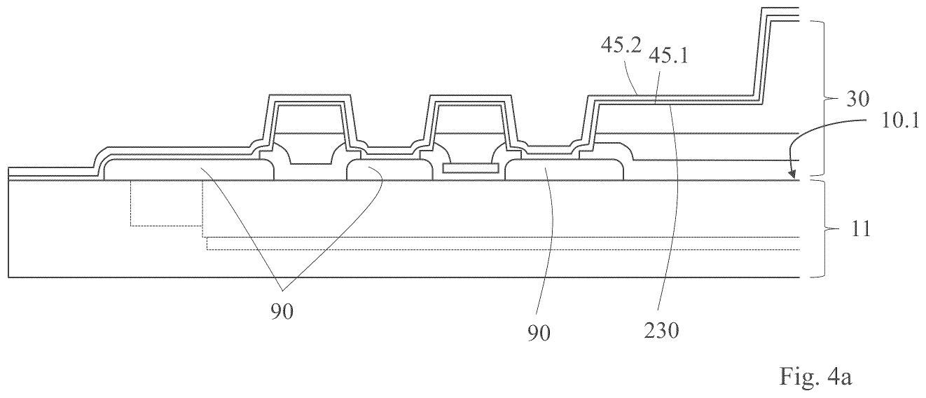

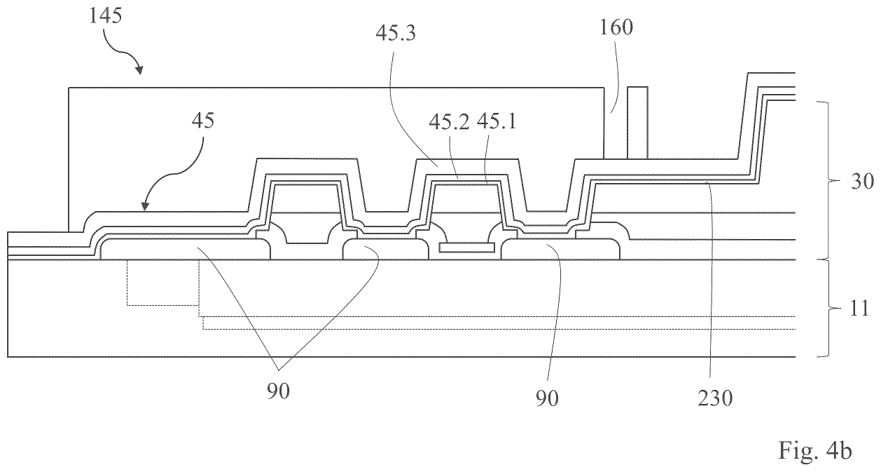

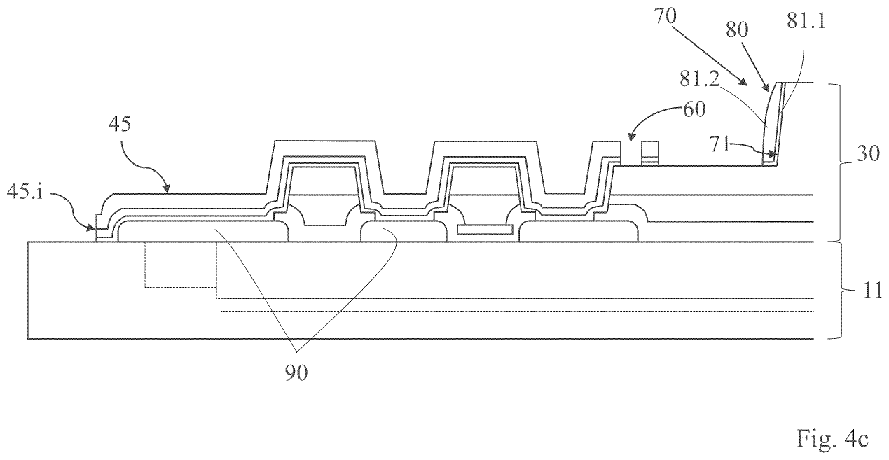

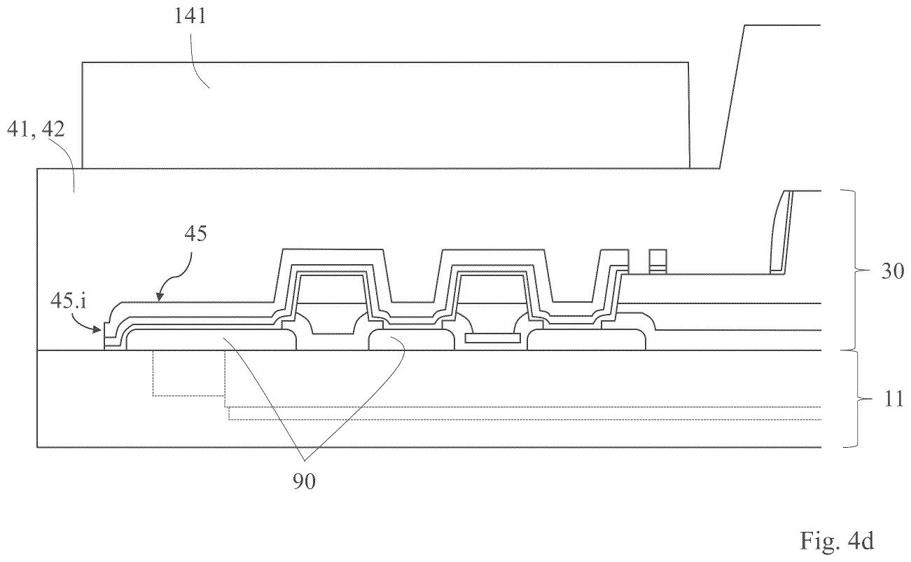

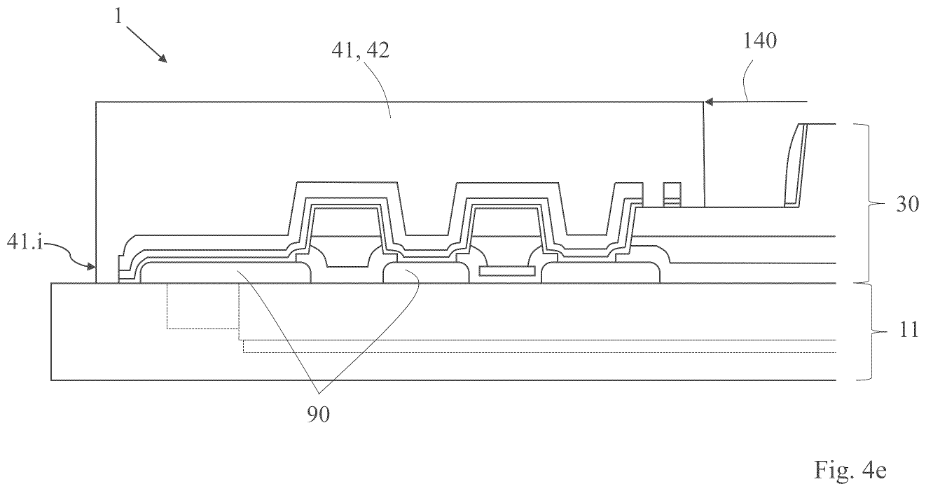

On the metallization 30, a passivation system 40 is arranged, which in the example shown comprises an inorganic passivation layer system 45 and an organic layer 41, e.g. imide layer 42, on the inorganic passivation layer system 45. As discussed in further detail with reference to FIG. 4e, an additional adhesion promoter layer can be arranged in between (not shown here).

The inorganic passivation layer system 45 shown comprises a first silicon nitride layer 45.1, an undoped silicon oxide layer 45.2 directly on the first silicon nitride layer 45.1, and a second silicon nitride layer 45.3 directly on the undoped silicon oxide layer 45.2. The passivation system 40 covers the gate runner 32 and source runner 33 and covers also the insulating layer 90 made of doped oxide (e.g. borophosphosilicate glass, BPSG). In the example shown, an aluminum oxide layer 340 (shown only as a line in FIG. 1) is arranged below the inorganic passivation layer system 45, i.e. on the insulating layer 90 and also on the metallization 30.

The sectional plane of FIG. 1 lies perpendicular to a lateral edge 31.1 of the load pad 31. The passivation system 40 extends between an outer lateral position x₁ aside the load pad and an inner lateral position x₂ which lies on the load pad 31, i.e. covers the lateral edge 31.1 of the load pad 31. In the embodiment shown, an interruption 60 is provided in at least one layer 41, 42, 45.1-45.3 of the passivation system 40, in this case the interruption 60 intersects the inorganic passivation layer system 45 completely. It is arranged at an interruption position xᵢ laterally between the lateral edge 31.1 of the load pad 31 and the inner lateral position x₂.

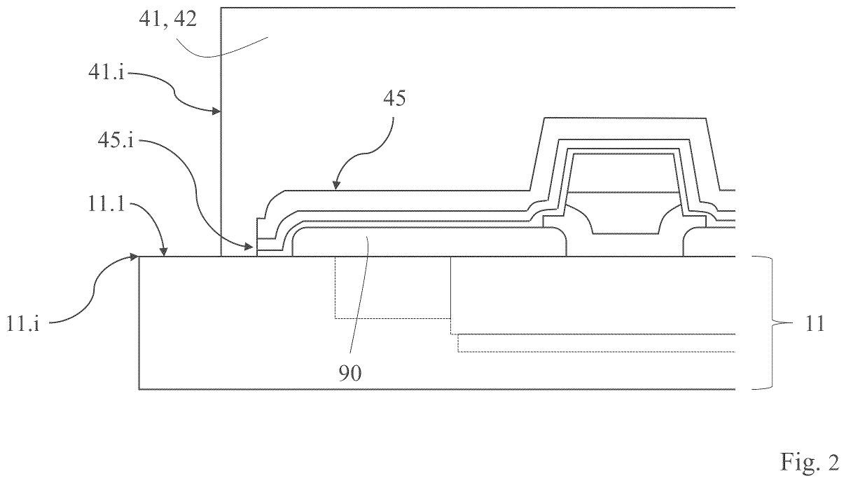

FIG. 2 shows a more detailed view of a lateral edge 45.i of the inorganic passivation layer system 45, which is arranged on the SiC semiconductor body 11, wherein the sectional plane lies perpendicular to this lateral edge 45.i. The lateral edge 45.i of the inorganic passivation layer system 45 is offset inwards from a lateral edge 11.i of the SiC semiconductor body 11. The organic layer 41, e.g. imide layer 42 in the example shown, extends further outwards and covers the lateral edge 45.i of the inorganic passivation layer system 45. Consequently, an outer lateral edge 41.i of the organic layer 41 is arranged further outward, i.e. closer to the lateral edge 11.i of the SiC semiconductor body 11, than the lateral edge 45.i of the inorganic passivation layer system 45.

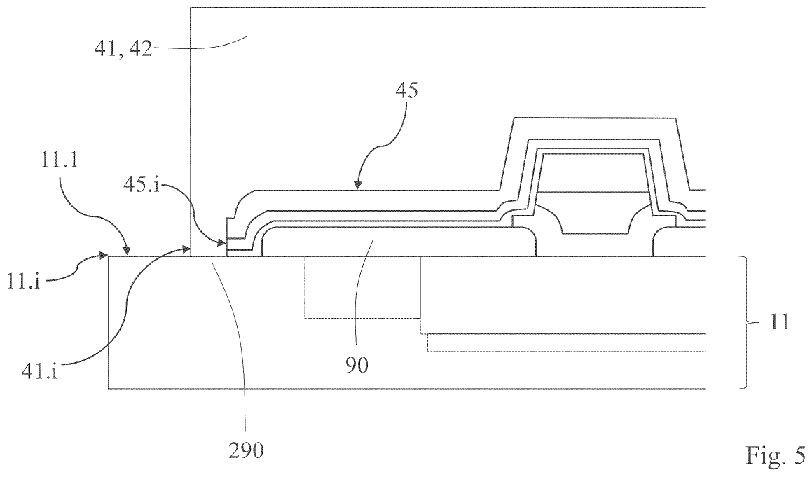

In the example shown, the inorganic passivation layer system 45, i.e. the first silicon nitride layer 45.1, and the organic layer 41 are respectively arranged directly on the first side 11.1 of the SiC semiconductor body 11, namely the inorganic passivation layer system 45 laterally outside of the insulating layer 90 and the organic layer 41 laterally outside of the lateral edge 45.i of the inorganic passivation layer system. Alternatively, however, an additional layer may be arranged in between, e.g. an aluminum oxide layer (see FIG. 5 for illustration).

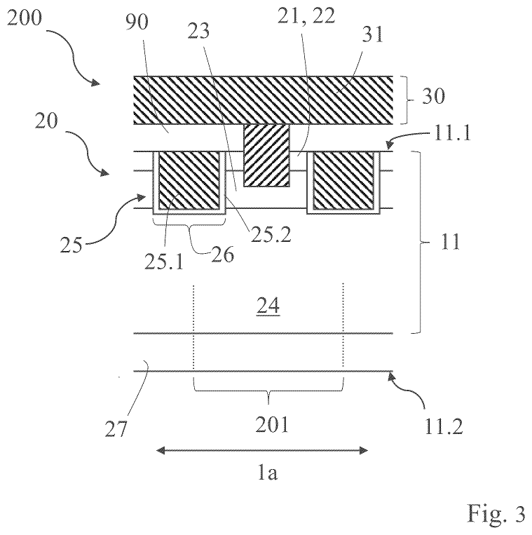

FIG. 3 illustrates a possible device 200 and device structure 20 formed in the active area 1a of the die 1, e.g. below the load pad 31 (see FIG. 1 for comparison). In the SiC semiconductor body 11, a load terminal 21 is formed at the first side 11.1, which is a source region 22 in the example shown. At the vertically opposite second side 11.2, a drain region 27 is arranged, wherein a body region 23 disposed below the source region 22 and a drift region 24 is arranged between the body region 23 and the drain region 27.

A gate region 25 comprising a gate electrode 25.1 and a gate dielectric 25.2 capacitively coupling the gate electrode 25.1 to the body region 23 is arranged in a trench 26. Via a voltage applied to the gate electrode 25.1, a channel formation in the body region 23 and, in consequence, current flow between the source region 22 and drain region 25 can be controlled. The device 200 may comprise a plurality of device cells 201 connected in parallel.

FIGS. 4a-e illustrate some steps for manufacturing a semiconductor die having a semiconductor body, and a metallization and a passivation system. In FIG. 4a, the insulating layer 90 has already been deposited onto the first side 11.1 of the semiconductor body 11 and the metallization 30 has been formed. Onto the metallization 30, the aluminum oxide layer 230 has been deposited (shown only as a line) and the silicon nitride layer 45.1 and the silicon oxide layer 45.2 have been deposited.

Prior to covering the silicon oxide layer 45.2 by the second silicon nitride layer 45.3 as shown in FIG. 4b, the silicon oxide layer 45.2 may be etched back (not shown in detail here). In FIG. 4b, the inorganic passivation layer system 45 has been deposited but not structured yet. For that purpose, a mask 145 is provided on the inorganic passivation layer system 45. The mask 145 has an opening 160 defining where the interruption is to be etched into the inorganic passivation layer system 45. Further, the mask 145 defines an inner and outer lateral end of the inorganic passivation layer system 45, i.e. where the inorganic passivation layer system 45 is to be opened on the load pad 31.

FIG. 4c illustrates the inorganic passivation layer system 45 after the etch step, i.e. after the interruption 60 has been etched into the inorganic passivation layer system 45 and the lateral edge 45.i of the inorganic passivation layer system 45 has been defined. E.g. applying an anisotropic etch step may leave inorganic layers 81.1, 81.2, e.g. a stack 80 of inorganic layers 81.1, 81.2, on the flank 71 of the step 70.

In a subsequent step illustrated in FIG. 4d, the organic layer 41, e.g. imide layer 42 in the example shown, has been deposited onto the structured inorganic passivation layer system 45. For a structuring of the organic layer 41, a mask 141 is formed on the organic layer 41. The mask 141 defines the lateral edge 41.i and the opening 140 in the organic layer 41, see FIG. 4e for illustration. In this process step, the organic layer 41 has been etched back and the mask has been removed from the organic layer 41.

FIG. 5 shows a detailed view of a lateral edge 11.i of the SiC semiconductor body 11. The embodiment shown in FIG. 5 differs from the embodiment illustrated in FIG. 2 in that the inorganic passivation layer system 45 and the organic layer 41, e.g. imide layer 42, are not arranged directly on the first side 11.1 of the SiC semiconductor body 11 laterally outside of the insulating layer 90. Instead, an adhesion promoter or etch stop layer 290 is arranged in between, which is an aluminum oxide layer in the example shown.

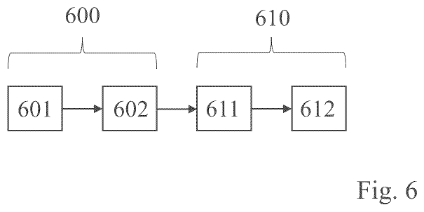

FIG. 6 summarizes some manufacturing steps in a flow diagram. Forming 600 an inorganic passivation layer system on a first side of a SiC semiconductor body may comprise depositing 601 the inorganic passivation layer system on the first side, wherein the inorganic passivation layer system is subsequently etched away 602 locally to define a lateral edge of the inorganic passivation layer system. Subsequently, the organic layer may be formed 610, e.g. by depositing 611 the organic layer and etching it away 612 locally to define an opening and a lateral edge.

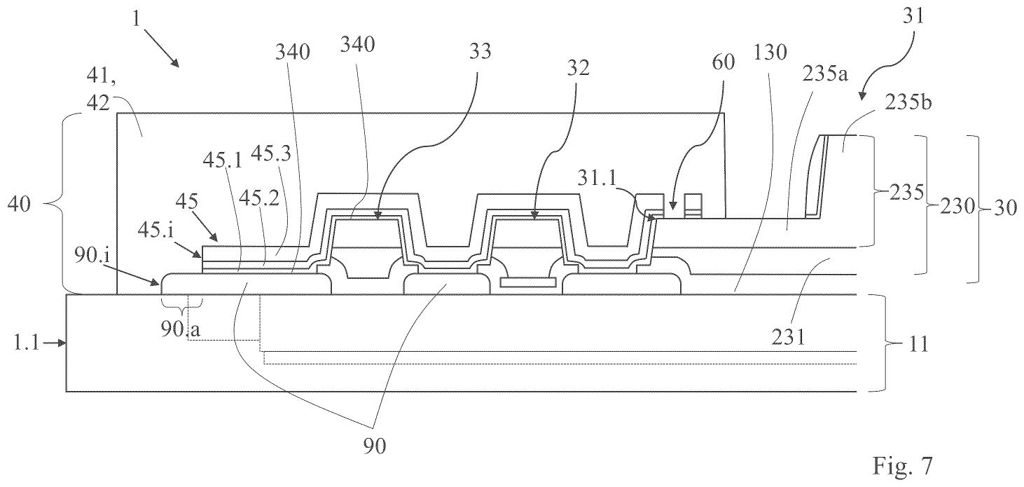

FIG. 7 shows an embodiment which differs partly from the one discussed with reference to FIG. 1. Also in this case, an insulating layer 90, a metallization 30 and a passivation system 40 are arranged on the first side 11.1 of the SiC semiconductor body 11 (see the description above for further details). In contrast to FIG. 1, the outer lateral edge 45.i of the inorganic passivation layer system 45 is not arranged aside the insulating layer 90, but on the insulating layer 90. Consequently, a portion 90a of the insulating layer 90 aside the outer lateral edge 45.i of the inorganic passivation layer system 45, i.e. between the outer lateral edge 45.i of the inorganic passivation layer system 45 and the outer lateral edge 90.i of the insulating layer 90, is not covered by the inorganic passivation layer system 45.

The organic layer 41, e.g. imide layer 42, extends further outwards, i.e. in direction to the outer lateral edge 1.1 of the die 1, than the inorganic passivation layer system 45 and the insulating layer 90. It covers the outer lateral edge 45.i of the inorganic passivation layer system 45 and also the outer lateral edge 90.i of the insulating layer 90.

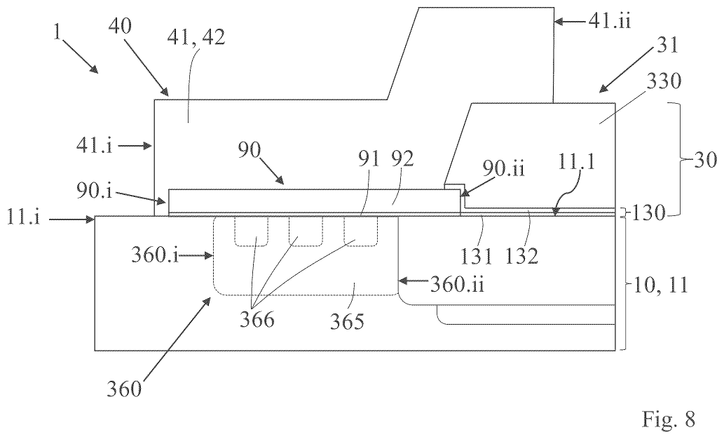

FIG. 8 shows a further embodiment of a semiconductor die 1 in a vertical cross-section. The semiconductor die 1 comprises a semiconductor body 10, which is a silicon carbide (SiC) semiconductor body 11 in the example shown. FIG. 8 additionally illustrates a field reduction structure 360 formed in the SiC semiconductor body 11. It comprises a doping well 365, into which a plurality of laterally staggered doped rings 366 are embedded, so that a doping concentration decreases stepwise towards the lateral edge 11.i of the SiC semiconductor body 11. In the example shown, the doping well 365 and the doped rings 366 have a second doping type, which may be p-type.

On a first side 11.1 of the SiC semiconductor body 11, a metallization 30 is arranged. The metallization 30 shown in FIG. 8 comprises a barrier layer system 130, e.g. with a first layer 131 and a second layer 132. The first and/or second layer 131, 132 may respectively comprise at least one of Ti, TiN, Ta, TaN, TiW, W or NiAl. On the barrier layer system 130, an aluminum or copper layer 330 is arranged, e.g. made of AlCu in the example of FIG. 8.

An insulating layer 90 is arranged on the first side 11.1 of the SiC semiconductor body 11. In the example shown, the insulating layer 90 comprises a first oxide layer 91 and a second oxide layer 92. The first oxide layer 91 may be an undoped oxide, e.g. formed as a gate oxide layer, which may serve as a gate dielectric in the active area of the die 1. The second oxide layer 92 may be undoped or doped. It can for instance be a silicon glass layer, e.g. USG, PSG or BPSG layer. The second oxide layer 92 may be arranged on, e.g. directly on, the first oxide layer 91.

On the insulating layer 90 and/or on the metallization 30, a passivation system 40 is arranged. It comprises an organic layer 41, for example an imide layer 42. In contrast to embodiments discussed above, the passivation system 40 depicted in FIG. 8 does not comprise an inorganic passivation layer system. In other words, the organic layer 41 may be arranged on the insulating layer 90 without an inorganic passivation layer system in between. For instance, the organic layer 41 may be arranged directly on the insulating layer 90.

An outer lateral edge 90.i of the insulating layer 90 is arranged on the SiC semiconductor body 11 and offset inwards from the lateral edge 11.i of the SiC semiconductor body 11. The organic layer 41, e.g. imide layer 42, extends further outward and covers the outer lateral edge 90.i of the insulating layer 90. In other words, the outer lateral edge 90.i of the insulating layer 90 is offset inward from an outer lateral edge 41.i of the organic layer 41. By way of example, the outer lateral edge 90.i of the insulating layer 90 may be offset inward by at least 1 μm and at most 100 μm (e.g. 2 μm-20 μm or 2 μm-10 μm) from the outer lateral edge 41.i of the organic layer 41.

An inner lateral edge 41.ii of the organic layer 41 is arranged on the metallization 30. The metallization 30 may form a load pad 31, the inorganic layer 41 having an opening (not referenced) on the load pad 31. The metallization 30 may extend onto the insulating layer 90, i.e. cover the inner lateral edge 90.ii of the insulating layer 90. In detail, the first barrier layer 131 may extend aside the insulating layer 90, whereas the second barrier layer 132 extends across the inner lateral edge 90.ii and reaches onto the insulating layer 90.

The insulating layer 90 may be arranged to cover the field reduction structure 360 vertically upwards. In detail, the outer lateral edge 90.i of the insulating layer 90 is arranged further outward than an outer lateral edge 360.i of the field reduction structure 360, and the inner lateral edge 90.ii of the insulating layer 90 is arranged further inward than the inner lateral edge 360.ii of the field reduction structure 360.

1. A semiconductor die, comprising:
a silicon carbide (SiC) semiconductor body; and
a passivation system on a first side of the SiC semiconductor body,
wherein the passivation system comprises an inorganic passivation layer system and an organic layer on the inorganic passivation layer system,
wherein a lateral edge of the inorganic passivation layer system is arranged on the SiC semiconductor body,
wherein the inorganic passivation layer system is laterally set back under the organic layer,
wherein the lateral edge of the inorganic passivation layer system is covered by the organic layer.

2. The semiconductor die of claim 1, wherein the inorganic passivation layer system is laterally set back under the organic layer by at least 1 μm.

3. The semiconductor die of claim 1, wherein the lateral edge is an outer lateral edge of the inorganic passivation layer system, which is offset inwards from a lateral edge of the SiC semiconductor body.

4. The semiconductor die of claim 3, wherein the lateral edge of the inorganic passivation layer system is arranged between the lateral edge of the SiC semiconductor body and an active area of the semiconductor die.

5. The semiconductor die of claim 3, comprising:
an insulating layer on the first side of the SiC semiconductor body,
wherein the insulating layer has an outer lateral edge on the SiC semiconductor body, wherein the outer lateral edge of the insulating layer is offset inwards from the lateral edge of the inorganic passivation layer system.

6. The semiconductor die of claim 5, wherein the outer lateral edge of the insulating layer is offset inwards from the lateral edge of the inorganic passivation layer system by at least 1 μm.

7. The semiconductor die of claim 1, comprising:
a metallization on the first side of the SiC semiconductor body, in which a load pad is formed,
wherein the passivation system covers a lateral edge of the load pad and has an opening on the load pad.

8. The semiconductor die of claim 7, wherein the inorganic passivation layer system, as viewed in a sectional plane perpendicular to the lateral edge of the load pad, has an inner lateral end on the load pad, wherein the organic layer extends further inwards than the inorganic passivation layer system and covers the inner lateral end of the inorganic passivation layer system.

9. The semiconductor die of claim 8, wherein the inorganic passivation layer system, as viewed in a sectional plane perpendicular to the lateral edge of the load pad, extends uninterrupted between the inner lateral end of the inorganic passivation layer system and the lateral edge of the load pad.

10. The semiconductor die of claim 9, wherein a runner is formed aside the load pad in the metallization, wherein the inorganic passivation layer system is uninterrupted above the runner.

11. The semiconductor die of claim 7, wherein the metallization in the area of the load pad is formed with a step, wherein the load pad has a first thickness t₁ laterally outside of the step and a second thickness t₂ laterally inside of the step, where t₁ is smaller than t₂.

12. The semiconductor die of claim 11, wherein an inorganic layer or layer stack covers a flank of the step.

13. The semiconductor die of claim 7, wherein the metallization comprises a copper layer.

14. The semiconductor die of claim 1, wherein the inorganic passivation layer system comprises a silicon nitride layer and a silicon oxide layer.

15. A semiconductor die, comprising:
a silicon carbide (SiC) semiconductor body;
an insulating layer on a first side of the SiC semiconductor body; and
a passivation system on the first side of the SiC semiconductor body,
wherein the insulating layer has an outer lateral edge on the SiC semiconductor body,
wherein the passivation system comprises an organic layer on the insulating layer,
wherein the insulating layer is laterally set back under the organic layer,
wherein the outer lateral edge of the insulating layer is covered by the organic layer.

16. (canceled)

17. The semiconductor die of claim 15, wherein the organic layer has a thickness of at least one of at least 1 μm or at most 50 μm.

18. The semiconductor die of claim 15, wherein the organic layer is an imide layer.

19. A method of manufacturing a semiconductor die, comprising:
forming an inorganic passivation layer system on a first side of a silicon carbide (SiC) semiconductor body, so that a lateral edge of the inorganic passivation layer system is arranged on the SiC semiconductor body; and
forming an organic layer on the inorganic passivation layer system, which covers the lateral edge of the inorganic passivation layer system.

20. The method of claim 19, wherein forming the inorganic passivation layer system comprises:
depositing the inorganic passivation layer system on the first side of the SiC semiconductor body; and
etching away the inorganic passivation layer system locally to define the lateral edge of the inorganic passivation layer system.
